(19) United States
(12) Patent Application Publication
(10) Pub. No.: US 2013/0308665 A1
(43) Pub. Date: Nov. 21, 2013

(54) TUNABLE SEMICONDUCTOR LASER DEVICE AND METHOD FOR OPERATING A TUNABLE SEMICONDUCTOR LASER DEVICE

(71) Applicants: Michael Engelmann, Breda (NL); Bob Van-Someren, Breda (NL)

(72) Inventors: Michael Engelmann, Breda (NL); Bob Van-Someren, Breda (NL)

(73) Assignee: EUPHOENIX, Breda (NL)

(21) Appl. No.: 13/990,899

(22) PCT Filed: Nov. 11, 2011
(86) PCT No.: PCT/NL11/50775

§ 371 Date: Aug. 5, 2013

(30) Foreign Application Priority Data
Dec. 2, 2010 (NL) 1038419

(51) Int. Cl. H01S 5/06

(52) U.S. Cl. CPC H01S 5/06
USPC 372/20

(57) ABSTRACT

A tunable semiconductor laser device includes a semiconductor structure, a longitudinal structure provided on the top surface of the semiconductor structure, a first longitudinal interdigitated transducer, wherein the first IDT is arranged on one lateral side of the longitudinal structure and at a distance along the lateral axis from said structure and parallel to the longitudinal structure.

### FIELD OF THE INVENTION

The invention relates to a tunable semiconductor laser device comprising a surface acoustic wave (SAW) resonator. In particular, the invention relates to such a device comprising an interdigitated transducer (IDT). The invention further relates to the use of such a tunable semiconductor laser device.

### BACKGROUND OF THE INVENTION

Semiconductor laser devices, such as for example laser diodes, can be formed from semiconductor material, for example III-V material, with a p-n junction. Various structures are known to a skilled person. The earliest designs are homostructure lasers having a single p-n junction. More modern designs such as the double heterostructure (DH) laser diodes have a layer with a narrow energy bandgap sandwiched between two layers of a wider energy bandgap semiconductor. In general, the two heterojunctions help to confine the carriers in the central layer, which is usually called the active layer. The layers surrounding the central layer are also known as cladding layers. If the middle or active layer is made thin enough, it acts as a quantum well, confining the electron hole pairs, which further improves the efficiency of the laser.

A semiconductor laser can be formed by doping a thin layer of a crystal wafer. The crystal is doped to produce an n-type region and a p-type region, resulting in a p-n junction. To confine the light in the p-n junction, the heterostructure itself is sandwiched between two layers of lower index of refraction than the heterostructure, the latter layers thus forming a cladding, causing confinement of the light in the heterostructure. By this construction, the active layer forms a waveguide from which the light cannot escape, except at end facets of the laser diode device, where the light is meant, by design, to leave the device. A diode laser using this layer stack is also referred to as the separate confinement heterostructure quantum well laser diode (SCHQW laser diode).

Laser diode devices may be powered in various ways. Two common ways are current injection (e.g. through electrodes or contact pads on the semiconductor material) or optical pumping (e.g. by another laser or a broadband radiation source). A forward current passed through the junction causes electrons and holes to be injected into the p-n junction. If electrons and holes are present in the same region they may spontaneously recombine, resulting in emission of photons.

Subsequently these photons can stimulate further recombinations in the active layer and thereby cause amplification. Another way of creating electron-hole pairs in semiconductor lasers is optical pumping. In that case doping is not required.

Besides input power, a functional semiconductor laser requires an optical feedback mechanism, to ensure that the light does not immediately leave the active layer through the end facets, but is fed back into the active layer and causes more stimulated emission transitions. In general, optical feedback is required to make the device produce a laser beam. The region where optical gain exists, the active layer, forms in operation an optical amplifier. The feedback mechanism selects which wavelengths are fed back into the active layer for amplification and thus it is the feedback mechanism that determines the most important properties of the laser: the central wavelength and the laser linewidth. Known laser diodes utilize a variety of means for creating optical feedback.

One example is providing reflecting surfaces on the opposite ends of the active layer. This design is called a Fabry-Perot laser. Another means of creating an optical feedback mechanism is to engrave, for example by etching, a permanent periodical structure in the cladding near the active layer. The periodicity of the structure is chosen to selectively provide feedback for light with the desired laser wavelength by means of Bragg reflection. This type of laser is called a distributed feedback laser (DFB laser). In this type of laser, the optical field of the active layer can be said to be coupled to the periodical structure. Yet another example is formed by Distributed Bragg Reflection (DBR) lasers, where a Bragg grating is used at either end of the laser device instead of mirroring facets to provide optical feedback. A DFB laser can be described as a laser where, in contrast to a DBR laser, the optical feedback occurs over essentially the whole gain section of the laser.

In DFB semiconductor lasers, various types of coupling of the optical field of the active layer to the periodical structure are distinguished, for example index-, gain-, loss- or complex-coupling. A treatment on DFB lasers and various coupling mechanisms is given in for example H. Kogelnik and C. V. Shank, Coupled-Wave Theory of Distributed Feedback Lasers, J. Appl. Phys. 43 (5), 2327 (1972).

In the publication “Calculation of ‘delta n̂2’ and ‘kappa’ for an Acoustically Induced Distributed Bragg Reflector (ADBR)” (Irby and Hunt, IEEE Journal of Quantum Electronics, Vol. 34, No. 2, February 1998) a theoretical design for a diode laser with optical feedback generated by means of a surface acoustic wave traveling on top of the laser structure is disclosed, as shown in FIG. 1. The design is for a device 100 comprising a III-V substrate 101, in which an active layer 102 is formed. On the top surface 106 of the device, a contact pad 103 is provided for current injection, which current is again removed through bottom contact 107. Arrows 111, protruding from facet 112, indicate the longitudinal direction which is also the direction in which the laser beam will leave the device through facet 112. Between contact pad 103 and facet 112, an Interdigitated Transducer (IDT) 105 is provided for generating a traveling Surface Acoustic Wave (SAW) using the connected RF power source 109. Between the IDT and the contact pad 103, a reflector 104 is provided to prevent that the SAW travels in the direction opposite the laser output direction 111. Between the IDT and the end facet 112, the surface 106 is provided with a SAW absorber 110, to prevent reflections of the running SAW on the edge of the device.

A surface acoustic wave, which partially penetrates into the semiconductor material towards the active layer, will generate regular refractive index variations in the diode material. Mathematically, an index of refraction can be represented as a complex number n+ik, where k>0 signifies loss (dampening) and k<0 means gain. The regular index variations give rise to regular reflections, thus forming an acoustically induced Bragg grating. For lasers, SAWs having a frequency in the GHz range are indicated in order to set up a suitable Bragg grating. The goal of the device is thus to use the SAW to set up an acoustically induced Bragg grating which acts as a Bragg Reflector, so that what Irby and Hunt call a “Acoustically Induced Distributed Bragg Reflector (ADBR)” device is formed.

In the ADBR design the IDT is placed effectively on top of the active region in a certain section along the axis of the outgoing laser beam and generates a SAW that travels to another section along the axis of the outgoing laser beam for the purpose of generating feedback. This design requires multiple sections in the laser diode and the traveling SAW is susceptible to damping, therefore requiring higher power or power controlling measures like reflectors and absorbers. As a consequence of damping the SAW will generate different refractive index variations along the direction of the laser output. Damping can typically be 20-30 dB/cm*GHẑ2

Another drawback of the ADBR design is that the generated laser light will be Doppler shifted since the light reflects off a traveling SAW. It is also to be expected that the periodic metal lines of the IDT, placed directly above the path of the laser beam, may induce a loss-coupling in the laser. That is, the metal lines periodicity may set up fixed Bragg grating due to periodic dampening (loss-coupling) of the optical wave directly beneath the metal lines. Finally, the fact that the ADBR uses DBR requires a precise positioning between the IDT on one side and the reflecting end facet on the other side. No functional examples of a tunable laser based on this structure have been reported.

### SUMMARY OF THE INVENTION

It is a goal of the invention to provide an improved tunable laser device.

This goal is met by providing a tunable semiconductor laser device comprising
a semiconductor structure, said structure having end surfaces on opposing sides along a longitudinal axis through the structure, the semiconductor structure being formed to have an active region in an active layer between a top surface and a bottom surface of the structure, the top surface being in a plane defined by the longitudinal axis and a perpendicular lateral axis;
a longitudinal structure provided on the top surface of the semiconductor structure and longitudinally extending over the whole or at least a part of the distance between the two opposing end surfaces in a direction parallel to the longitudinal axis, said longitudinal structure being arranged to receive an electrical current through a contact surface;
a first longitudinal interdigitated transducer (IDT) provided either on the top surface or beneath the top surface having a projection on the top surface, said first IDT extending longitudinally in a direction parallel to the longitudinal axis and being arranged to, in response to a signal from a signal generator, generate a surface acoustic wave (SAW) in a direction parallel to the longitudinal axis, wherein the first IDT is arranged parallel to the longitudinal structure with the IDT or projection thereof and the longitudinal structure longitudinally extending at least partly side by side with each other, the centers of the IDT or projection thereof and the longitudinal structure being separated by a distance along the lateral axis.

In an embodiment, the invention thus provides a design where the IDT is placed laterally beside the active region (and beside the path of the laser beam) instead of directly above the active region (or at the very least along the path of the laser beam) as in the publication by Irby and Hunt. In addition, this arrangement allows the advantageous placement of the IDT besides essentially the whole or at least a significant part (for example, at least half or at least three quarters) of the active region. The embodiment, through the indicated separation of the centers of the longitudinal structure and the IDT, advantageously prevents the problem of loss-coupling through the periodicity of the IDT metal lines. The SAW structure will be designed such that an acoustic resonator will be formed in a region in the vicinity of the active layer of the laser, in which, upon excitation, a standing acoustic wave will be formed, thereby preventing the Doppler shift in the laser wavelength.

The end surfaces of the laser device may be end facets, but other boundaries of the semiconductor structure are also possible. The end surfaces must be designed such that they do not disturb the feedback e.g. by introducing strong Fabry Perot modes. This can be done by antireflection coatings, slightly diagonal ridge waveguides (e.g. 1-10 degrees) or by curving at least a portion for the ridge waveguide in order to reduce reflections from an end surface or by simply avoiding end surfaces by placement (“butt coupling”) of a light absorber on one side and for example an optical fiber or arrayed waveguide grating on the other side. Further, a situation can be imagined whereby a facet could handily be cleaved diagonally into the transversal direction in order to prevent SAWs from reflecting back along the surface but rather cause them to be scattered into the bulk of the material where they quickly are dissipated.

Power is coupled into the laser by injecting current through the longitudinal structure. Said current may be drained in a known way, for example via a further contact surface provided on the bottom surface. Other ways are also possible, including lateral power connections (current injection from side to side). The semiconductor laser may be a diode laser.

An IDT is an advantageous SAW transducer. An IDT may comprise interdigitated combs made of conducting lines. It may also comprise piezoelectric material. In principle, the invention is not limited to an IDT. The IDT may be replaced or supplemented by another device for inducing a SAW, such as a device for optical beat frequency excitation, or Gunn diodes, as long as the necessary precautions are taken, such as the prevention of a gain disturbance. In addition, a set of interdigitated fingers could be used to set up SAW resonator conditions only, whereas the actual SAW is generated elsewhere.

In an embodiment, IDTs with selective omission or modification in material or structure of one or more fingers may be used to produce additional longitudinal confinement. Different kinds of IDT designs like: weighted, bi- or unidirectional, split-finger, curved/corrugated, (un)apodized, superstructure grating, multimode, multielectrode, floating, phase-jump, broadband, higher harmonic or combinations etc may be used according the invention. These and other designs are for example elaborated in Hashimoto, Surface Acoustic Wave Devices in Telecommunications, Springer, 2000.

In an embodiment, the laser comprises a second longitudinal interdigitated transducer, IDT, provided either on the top surface or beneath the top surface having a projection on the top surface, said second IDT extending longitudinally in a direction parallel to the longitudinal axis and being arranged to, in response to a signal from a signal generator, generate a surface acoustic wave, SAW in a direction parallel to the longitudinal axis, wherein the second IDT is arranged parallel to the longitudinal structure with the second IDT or projection thereof and the longitudinal structure longitudinally extending at least partly side by side with each other, the centers of the second IDT or projection thereof and the longitudinal structure being separated by a distance along the lateral axis in a direction opposite the direction along the lateral axis separating the centers of the first IDT or projection thereof from the longitudinal structure.

The second IDT can thus be said to be provided on the opposite side of the longitudinal structure. In an embodiment, the first and second IDTs are provided symmetrically with respect to the central longitudinal structure. That is, the first IDT (or projection) is provided on one lateral side of the longitudinal structure at a lateral distance from the longitudinal structure, while the second IDT (or projection) is provided at the same lateral distance from the longitudinal structure, but displaced in the opposite direction. This symmetrical device advantageously allows the extremum of the combined SAW of the IDTs to be located on or beneath the longitudinal structure, thus in or near the active region of an operating laser. In an alternative formulation, the active region can be said to be inside the acoustic resonator formed by the combined IDTs.

In an embodiment according the invention, the second IDT is shorter as measured along the longitudinal axis and/or has a different periodicity than the first IDT. Advantageously, this heterogenous arrangement of two IDTs may provide coverage of multiple optical wavelengths or advantageous interaction of the two SAWs (difference-frequencies, amplitude or frequency attenuation, wider tuning ranges).

In an embodiment according the invention, the distance in the lateral direction between the longitudinal structure and the (comb) structure of the IDT is between 50 nm and 100 micron (μm), preferably between 100 nm-10 micron. These distances may give adequate SAW induced gratings while preventing loss coupling. In an embodiment according the invention, the distance between the center of the active region and the (comb) structure of the IDT is between 50 nm and 150 micron (μm), preferably between 100 nm-15 micron.

In an embodiment according the invention, the device is adapted for forming, under operating conditions, a Bragg grating having an uneven order with respect to the desired laser wavelength, preferably a low uneven order, such as first order, third order, or fifth order, even more preferably third order. An operating parameter is the order n of the Bragg grating. A lower order requires a higher RF frequency, whereas a higher order has more advantageous minimum feature sizes.

In an embodiment according the invention, the semiconductor structure comprises III-V semiconductor materials, such as gallium arsenide, indium phosphite, gallium antimonide, and gallium nitride or alloys of these, such as InGaAsP—InP Other materials can be found in the II-VI groups.

In an embodiment according the invention, each IDT is a single-finger unapodized IDT comprising a plurality of interleaved conducting lines surrounded by or placed on top of piezoelectric material. In an embodiment according the invention, the piezeoelectric material is one or a combination of Quartz, Lithium Niobate, Zinc Oxide, or non-doped semiconductors like InP, GaSb or GaAs.

In an embodiment according the invention, the interleaved conducting lines are 20-200 nm, preferably 50-100 nm, high and 10-250 micron, preferably 20-100 micron long.

In an embodiment according the invention, the semiconductor structure and the piezoelectric material comprise the same semiconductor material and are monolithically formed.

In an embodiment according the invention, each IDT is symmetrically positioned with respect to the end surfaces.

In an embodiment according the invention, the longitudinal structure has a height, extending in a direction protruding from the top surface, of at least 0.05 micron, preferably at least 0.1 micron, and at most 0.5 micron.

In an embodiment according the invention, the longitudinal structure forms an optical ridge waveguide, said structure having a height, extending in a direction protruding from the top surface, of at least 0.5 micron, such as at least 1 micron or at least 2 micron.

In an embodiment according the invention, the device further comprising at least one integrated signal generator, wherein each IDT is connected to a signal generator.

The invention further provides a method of operating a tunable semiconductor laser device, the method comprising
providing a tunable semiconductor laser according to any of the preceding claims;
supplying optical or electrical power to said laser;
supplying an electrical signal to the IDT;
controlling the electrical signal to the IDT to control the wavelength of the laser beam generated by the laser.

An embodiment according the invention can alternatively be described as follows. In a semiconductor laser having one or more IDTs, each IDT can be described as extending over essentially the entire length of the active region. This advantageously allows the IDT to create optical feedback (through the acoustically induced Bragg grating) in essentially the entire active region (the SAW is expected to have the best properties in the center of the region, and may be less homogenous towards the ends). Thus, an acoustically induced Distributed Feedback (DFB) laser is formed, rather than an acoustically induced DBR laser as known from the prior art. Each IDT does not extend on top (transversal direction) of the center of this active region. This advantageously prevents loss-coupling with the light in the active region.

The one or more IDTs that extend over a significant part (i.e. more than half or more than three quarters) of the active region could even be provided on top of the center of the active region, provided that the IDTs are placed in such a manner that the (vertical) distance between the IDTs and the active region is enough to prevent loss coupling. A skilled person can determine the optimal distance by experimenting with various distances. If the distance is too small, the laser is not tunable and has a wavelength that is related to the fixed periodicity of the IDTs. If the distance is too large, the SAW does not influence the optical feedback sufficiently.

The invention may be practiced using an IDT, as described in the preceding. However, it is also possible to use, instead of an interdigitated transducer, a structure as described here. A short-circuited or “floating” row of conducting or metal wires, for example in the form of a kind of ladder or (“floating”) separate lines, could be used instead of the IDT. This ladder could cause an externally induced (e.g. by a device for optical beat frequency excitation) SAW to resonate. As such, the lines form a resonator only, not a transducer. Alternatively, two longitudinally arranged transducers may be provided, one on either side of the longitudinal structure, each transducer creating a travelling SAW which combines underneath the longitudinal structure to a standing wave. A further alternative is provided in an transducer like an IDT, except with a missing comb making it strictly speaking not interdigitated. Such a transducer can also be used to generate a SAW.

While the invention has been described by making references to a semiconductor laser with current injection, it is to be understood that the invention may also be applied to an optically pumped semiconductor laser device. In this case, the longitudinal structure and connected contact surfaces may be omitted, or at least do not need to be provided with a DC current in operation. Instead, a light source such as a smallband (diode) laser or broadband source is to be provided for optical pumping of the active region and subsequently no p or n doping is required.

### SHORT DESCRIPTION OF THE FIGURES

The invention will be explained in detail with reference to some drawings that are only intended to show embodiments of the invention and not to limit the scope. The scope of the invention is defined in the annexed claims.

On the attached drawing sheets,

FIG. 1 schematically shows a known design for an acoustically induced distributed Bragg reflection (ADBR) laser;

FIG. 2 schematically shows a top view of a tunable semiconductor laser according to an embodiment of the invention.

FIG. 3 schematically shows a side view of a tunable semiconductor laser according to an embodiment of the invention;

FIG. 4 schematically shows a perspective view of a tunable semiconductor laser according to an embodiment of the invention;

FIGS. 5 and 6 schematically shows a further side view of a tunable semiconductor laser according to an embodiment of the invention;

FIG. 7 schematically shows a detail of a tunable semiconductor laser according to an embodiment of the invention.

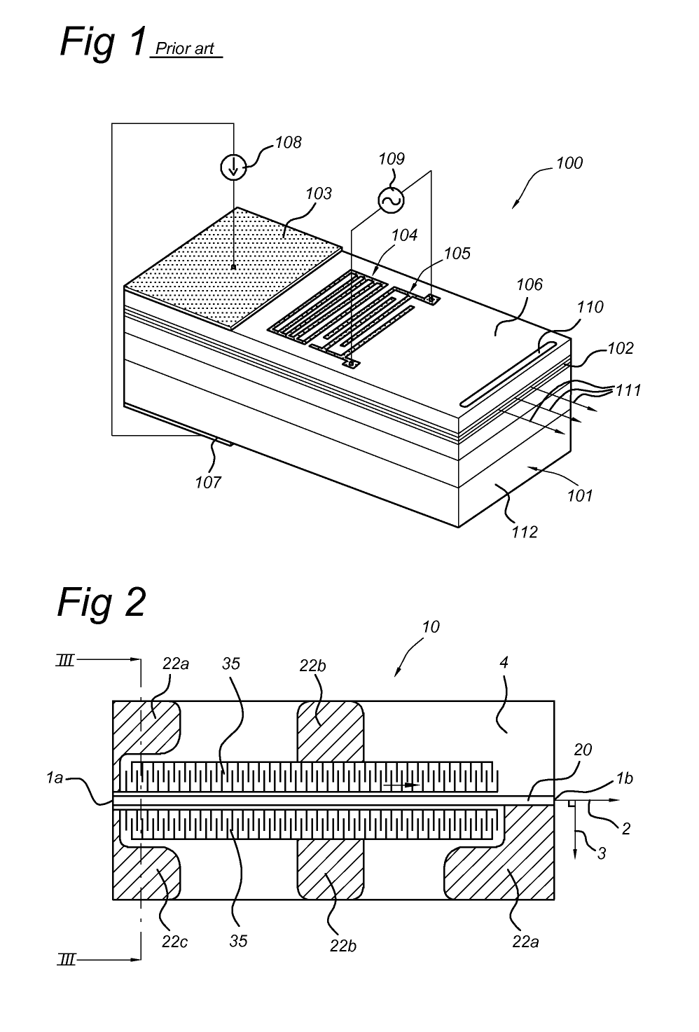

### DETAILED DESCRIPTION

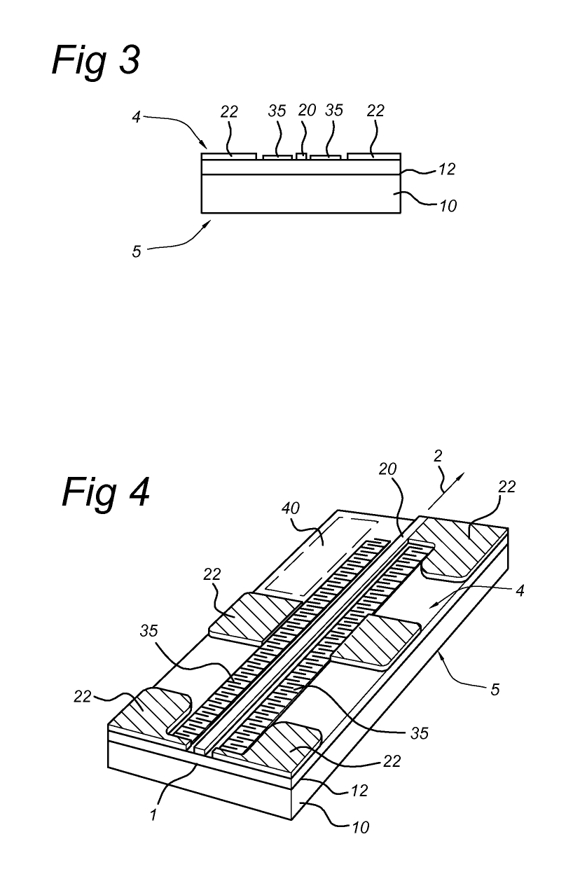

FIGS. 2, 3, and 4 schematically show respectively a top view, a side view, and a perspective view of a tunable semiconductor laser 10 according to an embodiment of the invention. The laser 10 comprises a diode structure having a p-n junction. In an example embodiment, the p-n junction is a III-V junction. Semiconductor lasers as such are known. Example laser diode designs are quantum cascade lasers, (separate confinement heterostructure), quantum well lasers, double heterostructure lasers, etc. Example materials for the diode structure are gallium arsenide (GaAs), indium phosphate (InP), gallium antimonide (GaSb), and gallium nitride (GaN) or mixtures of these, like InₓGa₁₋ₓAl_{y}As_{1-y}. It will be understood, however, by a person skilled in the art that other suitable materials exist and may be applied according the invention.

The laser 10 has a top surface 4 and a bottom surface 5, with an active layer 12 between the top and bottom surfaces. As described in the introduction, the active layer 12 may for example be a single p-n junction, or more advantageously a double heterostructure junction or a quantum well. Again, the skilled person will have access to many options for forming a suitable active layer 12. The laser 10 is provided with end facets 1a and 1b.

The coordinate system used in the description of the laser 10 will be the following. The laser is designed, as will be discussed in the following, to generate laser light along a longitudinal axis 2 in the direction of a line from the first end surface 1a to the second end surface 1b. As mentioned before, a wide variety of end surfaces may be provided. In the following example embodiments, the surfaces will be described as end facets. The lateral axis 3 is perpendicular to the longitudinal axis 2. Both lateral axis 3 and longitudinal axis 2 are parallel to the planes of the top surface 4, bottom surface 5, and active layer 12. Perpendicular to each plane, in other words extending in the direction of a line from the top surface 4 into the bulk of the diode towards the bottom surface 5, is the transversal direction. In the example embodiment of FIGS. 2 and 4, the longitudinal dimension of the laser 10 is larger than the lateral dimension. This is, however, not required by the invention. Example dimensions are between 0.1 and 5 mm (100-5000 micron) in the longitudinal dimension, and between 0.1 and 5 mm (100-5000 micron) in the lateral dimension, and 10-1000 micron in the transversal direction. Typical thickness (transversal dimension) of an active layer is 1-50 nm.

The top surface of the laser 10 is provided with a longitudinal structure 20. The longitudinal structure 20 may be a narrow conducting top contact, or a conducting stripe, for example being a few micron wide (lateral dimension). Alternatively, the longitudinal structure may be protruding from the top surface 4, having a height (transversal dimension) of at least 0.05 micron, preferably at least 0.5 micron, and at most 2 micron. Such a protruding longitudinal structure could also have the function of a (buried) ridge wave guide (RWG) which essentially supplies (additional) lateral confinement of the optical field and thereby can result in fewer optical modes and a narrower laser line width. A RWG typically includes the conducting top stripe for current injection. In principle also buried RWGs may be used according the invention which are typically a void or trench in the material roughly the size of a normal RWG.

The longitudinal structure 20 is electrically connected to contact pad 22a. The bottom surface 5 of the laser 10 is provided with a bottom contact surface. By connecting a positive DC to the top contact pad 22a and a ground DC voltage to the bottom contact surface, an electrical current may be injected into the laser.

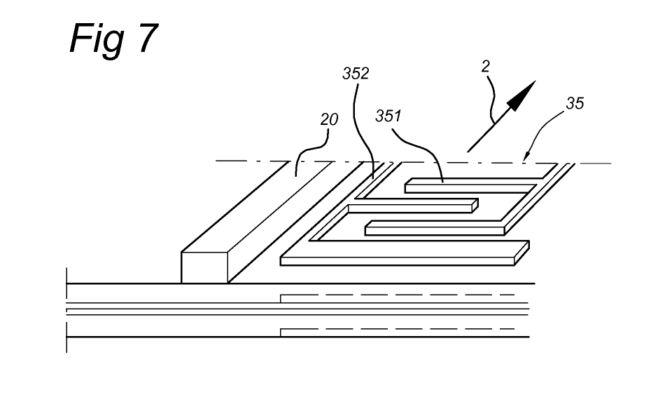

In the example embodiment of FIGS. 2, 3, and 4, the top surface 4 of laser 10 is provided with two acoustical interdigitated transducers (IDTs) 35. Each IDT 35 extends in a longitudinal direction and comprises two interlocking combs 351, 352 formed by wires made from a conducting material, such as a metal. In general, the combs can be described as interleaved areas of high (the wires) and low (the space between the wires) electrical conductivity. FIG. 7 provides a detail view. In addition, each IDT 35 may comprise specific piezoelectric materials.

Example piezoelectric materials are Quartz, Lithium Niobate, and Zinc Oxide or non-doped semiconductors like InP, GaSb or GaAs. The non doped semiconductor materials provide attractive process integration opportunities, such as a monolithic design where the bulk of the laser 10 and the IDT piezoelectric material comprise essentially the same material. The IDTs are provided with respective contact surfaces 22b, 22c for each respective comb. By applying an electrical signal from an signal generator, such as a Radio Frequency (RF) signal in the GHz range, a Surface Acoustic Wave (SAW) may be generated. Due to the longitudinal orientation of the IDTs, the SAWs will combine to form a single SAW and which forms a standing wave in the longitudinal direction.

Each IDT 35 is provided beside the longitudinal structure 20, the longitudinal center line of each IDT 35 being displaced along a lateral distance from the longitudinal center line of the longitudinal structure 20. The pair of IDTs in the example embodiment is arranged symmetrically with respect to the central longitudinal structure 20, that is a first IDT 35 is located at a lateral distance on one lateral side of the structure 20, and the second IDT 35 is located at the same lateral distance on the other lateral side of the structure 20. This symmetric arrangement advantageously allows the IDTs to be operated such that a combined SAW is generated having a extremum amplitude between the two IDTs, i.e. roughly at the position of the longitudinal structure 20 which in turn corresponds to the lateral position of the active region. The active region can be said to be inside or exactly below the SAW resonator.

However, the symmetrical design is not required according the inventions. Considerations such as design or contact surface lay-out issues may indicate a non-symmetrical arrangement of the IDTs. Also, according the invention an embodiment with just one IDT is also provided (see FIG. 6).

In operation, current is injected through contact surface 22a and longitudinal structure 20 into the bulk of the semiconductor material. The current is drained via a contact surface provided on the bottom surface 5. The current causes the creation of an active region where optical gain occurs in the active layer 12. The active region may typically be 1-10 micron wide and extends over essentially the entire length of the longitudinal structure 20 (for example, several hundred micron).

The IDTs typically create a standing SAW, by interference of two running waves with opposite directions, which is present over essentially the entire length (longitudinal dimension) of the IDTs, and thus over essentially the entire length of the active region. The SAW induces index of refraction variations in the laser material, which gives rise to a Bragg grating. The Bragg grating, having a periodicity that is determined by the frequency of the (RF) signal applied to the IDT and by the SAW velocity, and which can thus be controlled via the IDT signal generator, forms the optical feedback necessary for laser functioning. Thus, a DFB laser is formed. By controlling the frequency of the IDT, the laser wavelength may be controlled.

The laser light can exit the laser through cleaved end facet 1b, in a manner which is known from existing DFB laser designs.

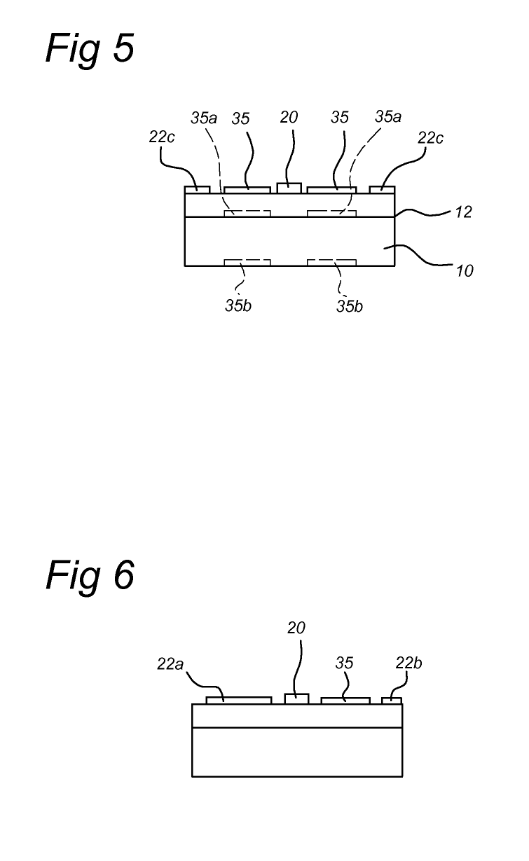

FIG. 5 shows a variation according to the invention. One or both IDTs 35 may be provided beneath the top surface 4 of the laser 10, inside the bulk material. The IDTs may be provided above (35a) or below (35b) the active layer 12. Having one or more IDTs inside the bulk material may provide for a more efficient use of the available top surface. IDTs in the bulk material can be connected to a signal generator through transversal (multilevel) connections. Additionally, a buried IDT may be used to create an improved SAW with better characteristics in the active region. In variants with IDT 35a, 35b beneath the top surface 4, the IDTs are still displaced along a lateral distance from the longitudinal structure 20. For IDTs 35a and 35b, the item indicated by numeral 35 in FIG. 5 is the projection of IDT 35a or 35b on the top surface. The projection 35 on the top surface of an IDT 35a, 35b located beneath the top surface can be described as running side by side with the longitudinal structure.

FIG. 6 shows a further alternative, already mentioned in connection with FIG. 2, where a single IDT 35 on one lateral side of the longitudinal structure 20 is provided.

FIG. 7, as mentioned, shows a detail of an IDT, indicating both combs of conducting wires with references 351 and 352. Typical dimensions for the conducting wires of an IDT may be 20-200 nm, preferably 30-100 nm, high (transversal dimension) and 10-250 micron, preferably 20-100 micron long (lateral direction). Alternatively, the longitudinal dimension is 5%-50%, preferably 20%-30% of the SAW wavelength.

In formula form, the optical wavelength λ_{optical} is determined by

λ_{optical}=2nv_{accoustic}/(of)

where n is the refractive index of the material, o is the (Bragg) grating order, v_{acoustic} the SAW velocity and f the RF frequency of the SAW.

The laser 10 may be combined with one or more integrated signal generators (not shown), in particular RF signal generators, so that each IDT 35 of the laser 10 is connected to an integrated signal generator. In such an embodiment, the contact pads 22b and 22c can be made smaller or eliminated altogether and replaced by conducting lines to the respective contact surfaces or connection points of the integrated signal generators. The skilled person will be aware of suitable signal generator designs that can be advantageously integrated with a tunable semiconductor laser according the invention, even integrated on the same chip as the semiconductor laser either monolithically (same material) or heterogeneously (different materials). In an advantageous variant, the integrated laser with signal generator is formed from essentially the same semiconductor material. By integrating these fuctionalities within one chip or at least package, the need to generate RF outside the laser package which would require cumbersome RF connections can be avoided.

In the foregoing description of the figures, the invention has been described with reference to specific embodiments thereof. It will, however, be evident that various modifications and changes may be made thereto without departing from the scope of the invention as summarized in the attached claims.

In particular, combinations of specific features of various aspects of the invention may be made. An embodiment of the invention may be further advantageously enhanced by adding a feature that was described in relation to another embodiment of the invention. For example, the skilled person will realize that the method of power supply through current injection or optical pumping does not necessarily influence the working of the IDTs, and that therefore embodiments with different IDT designs can be combined with different power supply variants.

In this document and in its claims, the verb “to comprise” and its conjugations are used in their non-limiting sense to mean that items following the word are included, without excluding items not specifically mentioned. In addition, reference to an element by the indefinite article “a” or “an” does not exclude the possibility that more than one of the element is present, unless the context clearly requires that there be one and only one of the elements. The indefinite article “a” or “an” thus usually means “at least one”.

1. Tunable semiconductor laser device comprising
a semiconductor structure (10), said structure having end surfaces (1a, 1b) on opposing sides along a longitudinal axis (2) through the structure, the semiconductor structure (10) being formed to have an active region in an active region layer (12) between a top surface (4) and a bottom surface (5) of the structure, the top surface being in a plane defined by the longitudinal axis (2) and a lateral axis (3) perpendicular to the longitudinal axis (2);
a longitudinal structure (20) provided on the top surface (4) of the semiconductor structure (10) and longitudinally extending over at least a part of the distance between the two opposing end surfaces (1a, 1b) in a direction parallel to the longitudinal axis (2), said longitudinal structure (20) being arranged to receive an electrical current through a contact surface (22);
a first longitudinal interdigitated transducer, IDT, (35) provided either on the top surface (4) or beneath the top surface having a projection on the top surface, said first IDT (35) extending longitudinally in a direction parallel to the longitudinal axis (2) and being arranged to, in response to a signal from a signal generator, generate a surface acoustic wave, SAW, in a direction parallel to the longitudinal axis (2),
wherein the first IDT (35) is arranged on one lateral side of the longitudinal structure (20) and at a distance along the lateral axis (3) from said structure and parallel to the longitudinal structure (20) with the IDT (35) or projection thereof and the longitudinal structure (20) longitudinally extending side by side with each other, and wherein the distance in the lateral direction between the longitudinal structure (20) and the IDT (35) is between 50 nm and 100 micron (μm).

2. Tunable semiconductor laser device according to claim 1, further comprising a second longitudinal interdigitated transducer, IDT, (35) provided either on the top surface (4) or beneath the top surface (4) having a projection on the top surface, said second IDT (35) extending longitudinally in a direction parallel to the longitudinal axis (2) and being arranged to, in response to a signal from a signal generator, generate a surface acoustic wave, SAW in a direction parallel to the longitudinal axis (2),
wherein the second IDT (35) is arranged on the opposite lateral side of the longitudinal structure (20) and at a distance along the lateral axis (3) from said structure and parallel to the longitudinal structure (20) with the second IDT (35) or projection thereof and the longitudinal structure (20) longitudinally extending side by side with each other, the second IDT (35) or projection thereof and the longitudinal structure (20) being separated by a distance between 50 nm and 100 micron (μηt) along the lateral axis (3) in a direction opposite the direction along the lateral axis (3) separating the first IDT (35) or projection thereof from the longitudinal structure (20).

3. Tunable semiconductor laser device according to claim 2, wherein the second IDT (35) is shorter as measured along the longitudinal axis (2) and/or has a different periodicity than the first IDT (35).

4. Tunable semiconductor laser device according to claim 1, wherein the distance in the lateral direction between the longitudinal structure (20) and the IDT (35) is between 100 nm-10 micron.

5. Tunable semiconductor laser device according to claim 1, wherein the device is adapted for forming, under operating conditions a Bragg grating having an uneven order.

6. Tunable semiconductor laser device according to claim 1, wherein the semiconductor structure (10) comprises III-V semiconductor materials.

7. Tunable semiconductor laser device according to claim 1, wherein each IDT (35) is a single-finger unapodized IDT comprising a plurality of interleaved conducting lines (351, 352) surrounded by or placed on top of or below piezoelectric material.

8. Tunable semiconductor laser device according to claim 7, wherein the piezeoelectric material is one or a combination of Quartz, Lithium Niobate, Zinc Oxide, or non-doped semiconductors.

9. Tunable semiconductor laser device according to claim 8, wherein the interleaved conducting lines (351, 352) are 20-200 nm, high and 10-250 micron long.

10. Tunable semiconductor laser device according claim 7, wherein the semiconductor structure (10) and the piezoelectric material comprise the same semiconductor material and are monolithically formed.

11. Tunable semiconductor laser device according to claim 1, wherein each IDT (35) is symmetrically positioned with respect to the end surfaces.

12. Tunable semiconductor laser device according to claim 1, wherein the longitudinal structure (20) has a height, extending in a direction protruding from the top surface (4), of at least 0.05 micron and at most 0.5 micron.

13. Tunable semiconductor laser device according to claim 1, wherein the longitudinal structure (20) forms an optical ridge waveguide, said structure having a height, extending in a direction protruding from the top surface (4), of at least 0.5 micron.

14. Tunable semiconductor laser device according to claim 1, the device further comprising at least one integrated signal generator (40), wherein in each IDT is connected to a signal generator.

15. Method of operating a tunable semiconductor laser device, the method comprising
providing a tunable semiconductor laser according to any of the preceding claims;
supplying optical or electrical power to said laser;
supplying an electrical signal to the IDT (35);
controlling the electrical signal to the IDT to control the wavelength of the laser beam generated by the laser.

16. Tunable semiconductor laser device according to claim 2, wherein the device is adapted for forming, under operating conditions a Bragg grating having an uneven order of the third order.

17. Tunable semiconductor laser device according to claim 2, wherein each IDT (35) is a single-finger unapodized IDT comprising a plurality of interleaved conducting lines (351, 352) surrounded by or placed on top of or below piezoelectric material.

18. Tunable semiconductor laser device according to claim 2, wherein each IDT (35) is symmetrically positioned with respect to the end surfaces.

19. Tunable semiconductor laser device according to claim 2, wherein the longitudinal structure (20) has a height, extending in a direction protruding from the top surface (4), of at least 0.05 micron and at most 0.5 micron.

20. Tunable semiconductor laser device according to claim 2, wherein the longitudinal structure (20) forms an optical ridge waveguide, said structure having a height, extending in a direction protruding from the top surface (4), of at least 0.5 micron.
